(19) United States
(12) Patent Application Publication
(10) Pub. No.: US 2024/0420929 A1
(43) Pub. Date: Dec. 19, 2024

(54) EXTREME EDGE FEATURE PROFILE TILT CONTROL BY ALTERING INPUT VOLTAGE WAVEFORM TO EDGE RING

(71) Applicant: Lam Research Corporation, Fremont, CA (US)

(72) Inventors: Rajesh Dorai, Pleasanton, CA (US); John Holland, San Jose, CA (US); Pratik Jacob Mankidy, Fremont, CA (US)

(21) Appl. No.: 18/702,320

(22) PCT Filed: Oct. 20, 2022
(86) PCT No.: PCT/US22/47326

§ 371 Date: Apr. 17, 2024

Related U.S. Application Data
(60) Provisional application No. 63/257,992, filed on Oct. 20, 2021.

(51) Int. Cl. H01J 37/32

(52) U.S. Cl. CPC H01J 37/32642; H01J 37/32091; H01J 37/32128; H01J 37/32146; H01J 37/32165; H01J 37/32183; H01J 37/32568; H01J 2237/3341

(57) ABSTRACT

A system for etching a wafer is provided. In one example, the system includes a lower electrode and an upper electrode disposed above the lower electrode. The system further includes an edge ring surrounding the lower electrode. The system includes a first radio frequency (RF) generator electrically coupled to the lower electrode and a second radio frequency (RF) generator electrically coupled to the edge ring. The system also includes a direct current (DC) bias generator for electrically supplying an additive DC bias to the edge ring. The system includes a controller interfaced with the first and second RF generators and the DC bias generator. The first RF generator is configured to produce a wafer voltage (V w) waveform at the lower electrode. The produced Vw waveform includes an induced direct current (DC) component and a first RF component produced by the first RF generator. The controller is configured to produce an edge ring voltage (V_{ER}) waveform for application to the edge ring. The V_{ER} waveform includes the additive DC bias and a second RF component produced by the second RF generator. The V_{ER} waveform is programmed by the controller to have a substantially same frequency and phase as the Vw waveform, a DC offset from the Vw waveform, and an amplitude variation relative to an amplitude of the Vw waveform.

### 1. FIELD OF THE INVENTION

The present embodiments relate to semiconductor fabrication, and more particularly to systems and methods for using a tailored voltage waveform at an edge ring of a plasma processing chamber.

### BACKGROUND

### 2. Description of the Related Art

Many modern semiconductor chip fabrication processes such as plasma etching processes are performed within a plasma processing chamber in which a substrate, e.g., wafer, is supported on an electrostatic chuck (ESC). In plasma etching processes, the wafer is exposed to a plasma generated within a plasma processing volume. Plasma contains various types of radicals, electrons, as well as positive and negative ions. The chemical reactions of the various radicals, electrons, positive ions, and negative ions are used to etch features, surfaces and materials of a wafer.

For example, when a process gas is supplied into the plasma processing chamber, a radio frequency (RF) signal provides power and is applied to at least one of the electrodes of the plasma processing chamber to form an electric field between the electrodes. The process gas is turned into plasma by the RF signal, thereby performing plasma etching on a predetermined layer disposed on the wafer. Unfortunately, during wafer processing, the plasma may result in an ion angular spread (e.g., ion tilt angles) occurring along the extreme edge of the wafer which may cause non-uniformity of features along the extreme edge of the wafer.

It is in this context that embodiments of the inventions arise.

### SUMMARY

Implementations of the present disclosure include devices, methods, and systems for controlling the ion angular spread (e.g., ion tilt angles) at the extreme edge of a wafer when supported on an electrostatic chuck (ESC) of a plasma process chamber during plasma etching processing. For example, the ion angular spread may include one or more ions that form an incidence angle that is other than normal to the surface of the wafer. In some embodiments, some ions can have an incidence that is normal to the surface of the wafer. When this occurs, an ion angular spread is formed along the extreme edge of the wafer which causes non-uniformity of features along the extreme edge of the wafer. In some embodiments, a system for etching a wafer includes producing an edge ring voltage (V_{ER}) waveform for application to the edge ring of the plasma process chamber. The V_{ER} waveform includes an additive direct current (DC) bias produced by a DC bias generator and a radio frequency (RF) component produced by an RF generator. In some embodiments, during plasma etching processing, the use of the V_{ER} waveform for application to the edge ring can cause the plasma sheath along the edge ring to be coplanar with the plasma sheath along the wafer. Thus, when ions are accelerated through the plasma sheath, the ion incidences will be substantially normal to the wafer which can result in a reduced ion angular spread. It should be appreciated that the present embodiments can be implemented in numerous ways, e.g., a process, an apparatus, a system, a device, or a method on a computer readable medium. Several embodiments are described below.

In one embodiment a system for etching a wafer is disclosed. The system includes a lower electrode and an upper electrode disposed above the lower electrode. The system further includes an edge ring surrounding the lower electrode. The system includes a first radio frequency (RF) generator electrically coupled to the lower electrode and a second radio frequency (RF) generator electrically coupled to the edge ring. The system also includes a direct current (DC) bias generator for electrically supplying an additive DC bias to the edge ring. The system includes a controller interfaced with the first and second RF generators and the DC bias generator. The first RF generator is configured to produce a wafer voltage (Vw) waveform at the lower electrode. The produced Vw waveform includes an induced direct current (DC) component and a first RF component produced by the first RF generator. The controller is configured to produce an edge ring voltage (V_{ER}) waveform for application to the edge ring. The V_{ER} waveform includes the additive DC bias and a second RF component produced by the second RF generator. The V_{ER} waveform is programmed by the controller to have a substantially same frequency and phase as the Vw waveform, a DC offset from the Vw waveform, and an amplitude variation relative to an amplitude of the Vw waveform.

In another embodiment, method for etching a wafer in a plasma system is described. The plasma system includes a lower electrode and an upper electrode disposed above the lower electrode, and an edge ring that surrounds the lower electrode. The method includes connecting a first radio frequency (RF) generator to the lower electrode and a second radio frequency (RF) generator to the edge ring. The method further includes connecting a direct current (DC) bias generator to the edge ring for supplying an additive DC bias to the edge ring. The first RF generator is configured to produce a wafer voltage (Vw) waveform at the lower electrode; the produced Vw waveform includes an induced direct current (DC) component and a first RF component produced by the first RF generator. The method includes generating an edge ring voltage (V_{ER}) waveform for application to the edge ring. The V_{ER} waveform includes the additive DC bias and a second RF component produced by the second RF generator. The V_{ER} waveform is set to have a substantially same frequency and phase as the Vw waveform, a DC offset from the Vw waveform, and an amplitude variation relative to an amplitude of the Vw waveform.

Several advantages of the herein described systems and methods for etching a wafer in a plasma system where the ion angular spread (e.g., ion tilt angles) at the extreme edge of a wafer is decrease by electrically supplying an additive DC bias to the edge ring of the plasma system. Instead of producing an edge ring voltage (V_{ER}) waveform for application to the edge ring that includes only an RF signal, the V_{ER} waveform also includes the additive DC bias. By electrically supplying an additive DC bias to the edge ring, the plasma sheath along the edge ring becomes coplanar with the plasma sheath along wafer sheath during a given pulse which results in the ion incidences being substantially normal to the wafer. As such, improvements in yield and etch uniformity along the extreme edge of the wafer is achieved.

Other aspects and advantages of the disclosure will become apparent from the following detailed description, taken in conjunction with the accompanying drawings, illustrating by way of example the principles of the disclosure.

### BRIEF DESCRIPTION OF THE DRAWINGS

The disclosure may be better understood by reference to the following description taken in conjunction with the accompanying drawings in which:

FIG. 1A illustrates an embodiment of a capacitive coupled plasma (CCP) processing system utilized for etching operations, in accordance with an implementation of the disclosure.

FIG. 1B illustrates an enlarged partial view of a section of the plasma process chamber shown in FIG. 1A during plasma etching processing, in accordance with an implementation of the disclosure.

FIG. 2 illustrates plasma generated during plasma etching processing using a new edge ring and a used edge ring, in accordance with an implementation of the disclosure.

FIGS. 3A-3B illustrate a plot of ion tilt angle (degrees) versus radial location along the top surface of the wafer for a new edge ring and a used edge ring, in accordance with an implementation of the disclosure.

FIG. 4A illustrates an embodiment of a graph to illustrate a wafer voltage (Vw) waveform signal generated by a low frequency (LF) radio frequency (RF) pulse generator, in accordance with an implementation of the disclosure.

FIGS. 4B-4C illustrate a plot of the ion tilt angle (degrees) versus radial location along the top surface of the wafer for a new edge ring and a used edge ring, respectively, in accordance with an implementation of the disclosure.

FIGS. 5A-5C illustrate the plasma sheath dynamics where the Child-Langmuir Law theorem is applied to demonstrate the required edge ring voltage and the wafer voltage that would cause the plasma sheath at the edge ring to be coplanar with the plasma sheath along the wafer, in accordance with an implementation of the disclosure.

FIGS. 6A-6B illustrate an example of an edge ring voltage (V_{ER}) waveform and a wafer voltage (Vw) waveform that can provide a coplanar plasma sheath edge along the edge ring and the wafer, in accordance with an implementation of the disclosure.

FIG. 7 shows an example schematic of the control system of FIG. 1A, in accordance with an implementation of the disclosure.

### DETAILED DESCRIPTION

The following implementations of the present disclosure provide devices, methods, and systems for controlling the ion angular spread (e.g., ion tilt angles) at the extreme edge of a wafer through the application of an edge ring voltage (V_{ER}) waveform. For example, the ion angular spread may include one or more ions that form an incidence angle that is other than normal to the surface of the wafer. When this occurs, an ion angular spread is formed along the extreme edge of the wafer which causes non-uniformity of features along the extreme edge of the wafer. In one embodiment, the V_{ER} waveform is applied to the edge ring of the plasma process chamber during plasma etching processing. In one embodiment, the V_{ER} waveform includes an additive direct current (DC) bias produced by a DC bias generator and a radio frequency (RF) component produced by an RF generator. During plasma etching processing, by producing a V_{ER} waveform for application to the edge ring that includes both the additive DC bias and the radio frequency (RF) component, the V_{ER} waveform causes the plasma sheath along the edge ring to be coplanar with the plasma sheath along the wafer. Accordingly, ion incidences at the extreme edge of the wafer will be substantially normal to the wafer resulting in a decrease in the ion angular spread at the extreme edge of a wafer. Thus, improvements in yield and etch uniformity along the extreme edge of the wafer can be achieved.

With the above overview in mind, the following provides several example figures to facilitate understanding of the example embodiments.

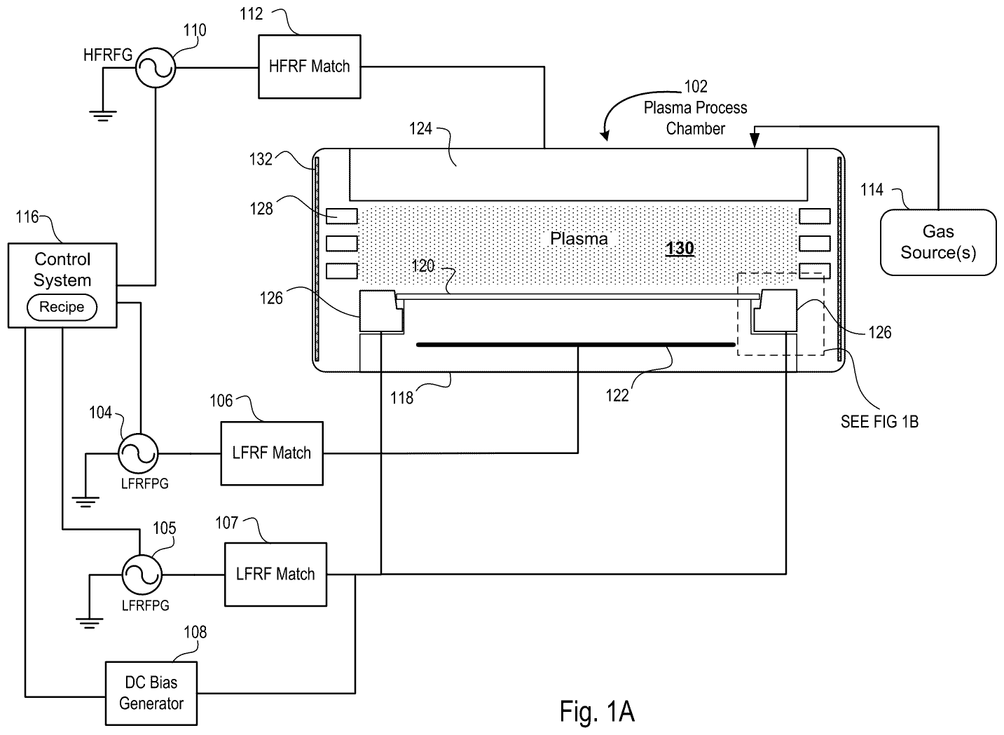

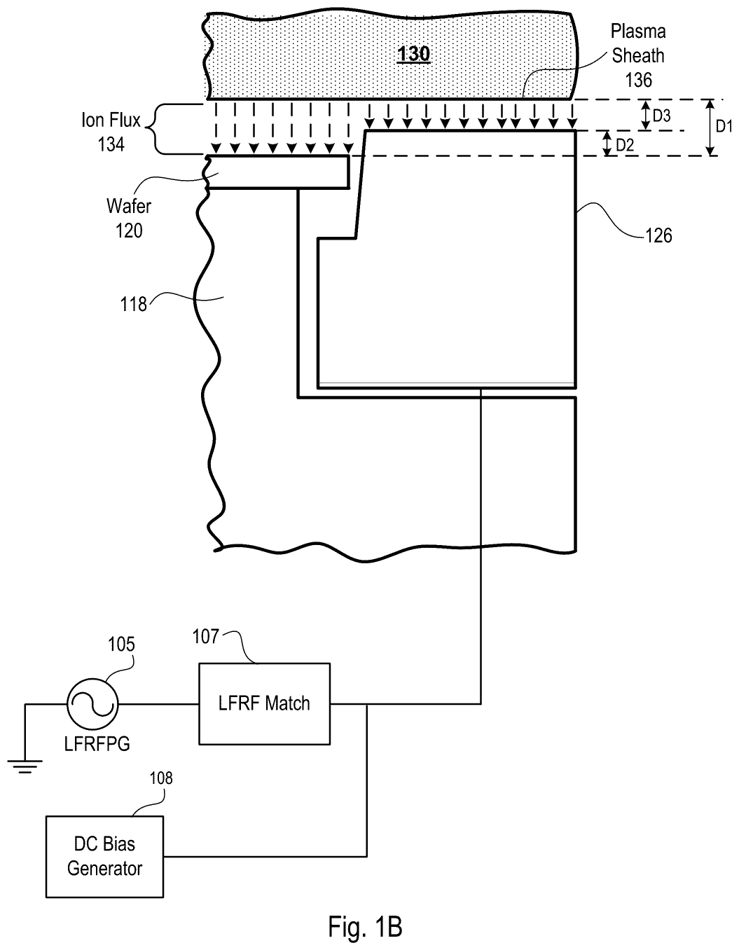

FIG. 1A illustrates an embodiment of a capacitive coupled plasma (CCP) processing system utilized for etching operations. The CCP processing system includes a plasma process chamber 102, a control system 116, a low frequency (LF) radio frequency (RF) pulse generator 104, a LF RF pulse generator 105, a LFRF match 106, a LFRF match 107, a direct current (DC) bias generator 108, a high frequency (HF) RF generator 110, a HFRF match 112, and one or more gas sources 114 that are coupled to the plasma process chamber 102.

In some embodiments, the system may include the control system 116 that is used for controlling various components of the CCP processing system. In one example, as shown in FIG. 1A, the control system 116 can be connected to the LFRF pulse generator 104, the LFRF pulse generator 105, the DC bias generator 108, the HFRFG 110, and the gas sources 114. The control system 116 includes a processor, memory, software logic, hardware logic and input and output subsystems from communicating with, monitoring and controlling the CCP processing system. In some embodiments, the control system 116 includes one or more recipes including multiple set points and various operating parameters (e.g., voltage, current, frequency, pressure, flow rate, power, temperature, etc.) for operating the CCP processing system.

As further illustrated in FIG. 1A, the system may include multiple RF sources that are capable of producing frequencies that can be used to achieve various tuning characteristics. As illustrated, the LFRF pulse generator 104 is connected to a lower electrode 122 via the LFRF match 106 and is configured to provide a pulsing RF signal to the ESC 118 to produce a wafer voltage (Vw) waveform at the lower electrode 122. In one embodiment, the LFRF pulse generator 104 is a sinusoidal-shaped pulse generator that generates a high-voltage nanosecond pulse periodically. In one embodiment, the pulse generator is a nanosecond pulser. In some embodiments, the LFRF pulse generator 104 may be configured to produce frequencies ranging from and including 10 kilohertz (kHz) to 800 kHz. For example, the frequency of operation of the LFRF pulse generator 104 is 400 kHz.

In some embodiments, the system further includes a LFRF match 106 circuitry that is coupled between the LFRF pulse generator 104 and the lower electrode 122. In one embodiment, the LFRF match 106 enables dynamic tuning of power provided to the lower electrode 122 of the plasma processing system. In one embodiment, the LFRF match 106 may include an impedance matching circuit or an impedance matching network. For example, the match is a series of circuit components, such as capacitors, inductors, and resistors where each of the circuit components are coupled to each other.

As further illustrated in FIG. 1A, the LFRF pulse generator 105 is connected to an edge ring 126 of the plasma process chamber 102 via the LFRF match 107. The LFRF pulse generator 105 is configured to provide a pulsing RF signal to the edge ring 126 to produce an edge ring voltage (V_{ER}) waveform for application to the edge ring. In one embodiment, LFRF pulse generator 105 is a sinusoidal-shaped pulse generator that generates a high-voltage nanosecond pulse periodically. In one embodiment, the pulse generator is a nanosecond pulser. In other embodiments, the LFRF pulse generator 105 may be configured to produce frequencies ranging from and including 10 kHz to 800 kHz. For example, the frequency of operation of the LFRF pulse generator 105 is 400 kHz. In one illustration, a frequency of operation of the LFRF pulse generator 105 is the same as the frequency of operation of the LFRF pulse generator 104. In other embodiments, a frequency of operation of the LFRF pulse generator 105 is different from the frequency of operation of the LFRF pulse generator 104.

In some embodiments, the system further includes a LFRF match 107 circuitry that is coupled between the LFRF pulse generator 105 and the edge ring 126. In one embodiment, the LFRF match 107 enables dynamic tuning of power provided to the edge ring 126 of the plasma processing system. Similar to the LFRF match 106, the LFRF match 107 may include an impedance matching circuit or an impedance matching network. For example, the match is a series of circuit components, such as capacitors, inductors, and resistors where each of the circuit components are coupled to each other.

In one embodiment, the DC bias generator 108 is configured to generate and to supply an additive DC bias to the edge ring 126. As illustrated in FIG. 1A, the DC bias generator 108 is connected to an edge ring 126 of the plasma process chamber 102. The DC bias generator 108 is configured to generate the additive DC bias which is combined with the RF signal generated by the LFRF pulse generator 105 to produce the V_{ER} waveform for application to the edge ring 126. As such, the V_{ER} waveform includes both the additive DC bias and the RF signal generated by the LFRF pulse generator 105 which is applied to the edge ring 126.

In one embodiment, by adding the additive DC bias to the V_{ER} waveform for application to the edge ring 126, this causes more direct power being applied to the edge ring 126. By powering the edge ring 126 with additive DC bias, the plasma sheath behaves consistently throughout the wafer 104 and the edge ring. In turn, the plasma sheath along the edge ring 126 becomes coplanar with the plasma sheath along the wafer sheath during a given pulse which results in the ion incidences being substantially normal to the wafer. As a result, ion angular spread (e.g., ion tilt angles) at the extreme edge of a wafer is reduced or eliminated. In one embodiment, the HFRFG 110 is connected to an upper electrode 124 via the HFRF match 112 and is configured to generate RF signals to the upper electrode 124 of the plasma processing chamber 102. In some embodiments, the HFRFG 110 may be configured to produce high frequencies ranging from and including 13 megahertz (MHz) to 120 MHZ. For example, the high frequency is a baseline frequency of 13.56 MHz or 27 MHz or 40 MHz or 60 MHz or 100 MHZ. To illustrate, a frequency of operation of the HFRFG 110 is about 13.56 MHz. The high frequency is greater than the low frequency produced by the LFRF generators. For example, the low frequency is 400 kHz and the high frequency is 13.56 MHZ. As another example, the low frequency is 100 kHz and the high frequency is 13.56 MHZ.

In some embodiments, the system further includes a HFRF match 112 circuitry that is coupled between the HFRFG 110 and the upper electrode 124. In one embodiment, the HFRF match 112 enables dynamic tuning of power provided to the upper electrode 124 of the plasma processing system. The HFRF match 112 may include an impedance matching circuit or an impedance matching network. In one example, the match is a series of circuit components, such as capacitors, inductors, and resistors where each of the circuit components are coupled to each other.

In another embodiment, the gas source 114 is connected to the plasma process chamber 102 and is configured to inject the desired process gas(es) into the plasma process chamber 102. After providing RF signals to the ESC 118 and injecting process gas into the plasma process chamber 102, plasma 130 is then formed between the upper electrode 124 and the ESC 118. The plasma 130 can be used to etch the surface of the wafer 120.

The plasma process chamber 102 includes an electrostatic chuck (ESC) 118 for supporting a wafer 120. The plasma process chamber 102 further includes a lower electrode 122 that is embedded within the ESC and an upper electrode 124 that is part of the ESC 118. The upper electrode 124 and the lower electrode 122 is made from a metal such as aluminum or an alloy of aluminum. The ESC 118 is made from the metal and from a ceramic, such as aluminum oxide (Al₂O₃). In some embodiments, the plasma process chamber 102 may include confinement rings 128 for confining plasma 130 during etching operations, and a chamber wall cover 132.

The plasma process chamber 102 also includes the edge ring 126, such as a tunable edge sheath (TES) ring, which surrounds the ESC 118. As an example, the edge ring 126 is fabricated from a conductive material, such as silicon, boron doped single crystalline silicon, silicon carbide, an alloy of silicon, or a combination thereof. It should be noted that the edge ring 126 has an annular body, such as a circular body, or ring-shaped body, or dish-shaped body. As an illustration, the edge ring 126 has an inner radius and an outer radius, and the inner radius is greater than a radius of the ESC 118. An example of the plasma process chamber 102 is a CCP chamber.

FIG. 1B illustrates an enlarged partial view of a section of the plasma process chamber 102 shown in FIG. 1A during an etching processing operation. As shown, the LFRF pulse generator 105 is connected to an edge ring 126 of the plasma process chamber 102 via the LFRF match 107. Further, the DC bias generator 108 is also connected to the edge ring 126. During etching operations, the LFRF pulse generator 105 and the DC bias generator 108 is configured to produce the V_{ER} waveform for application to the edge ring. As noted above, the V_{ER} waveform includes the additive DC bias generated by the DC bias generator 108 and the RF signal produced by the LFRF pulse generator 105. When the V_{ER} waveform is applied to the edge ring 126, ions are accelerated through the plasma sheath 136 resulting in an ion flux 134 that is more normal to the top surface of the wafer 120. For example, as illustrated, FIG. 1B provides a conceptual illustration of the trajectory of the ions from the plasma sheath 136 to the wafer 120 along the edge of the wafer where the resulting ion flux 134 is substantially normal (e.g., perpendicular) to the top surface of the wafer 120.

With the addition of the additive DC bias added to the V_{ER} waveform, the additive DC bias eliminates or reduces the ion angular spread (e.g., ion tilt angles) at the extreme edge of a wafer 120. Instead of having an ion angular spread where the ions form an incidence angle that is other than normal to a surface of the wafer 120, the additive DC bias causes the resulting ion flux 134 to be more perpendicular to the top surface of the wafer 120 since the plasma sheath 136 along the edge ring 126 becomes coplanar with the plasma sheath along the wafer 120. As a result, improvements in etch uniformity along the extreme edge of the wafer is achieved.

As further illustrated in FIG. 1B, the wafer 120 is supported by a top surface of the ESC 118. The wafer 120 and the ESC 118 are both surrounded by edge ring 126. As shown, distance D1 extends from the top surface of the wafer 120 to a bottom layer of the plasma sheath 136. As further illustrated, distance D2 extends from the top surface of the wafer 120 to the top surface of the edge ring 126. As further illustrated in FIG. 1B, distance D3 extends from the top surface of the edge ring 126 to the bottom layer of the plasma sheath 136. In one example, by maintaining a distance where D1 is greater than D2, the additive DC bias can cause a reduction in the ion angular spread. In other embodiments, if distance D1 is approximately the same as distance D2, or if D1 is less than D2, the ion energies would be so small causing the ion angular spread to be negligible.

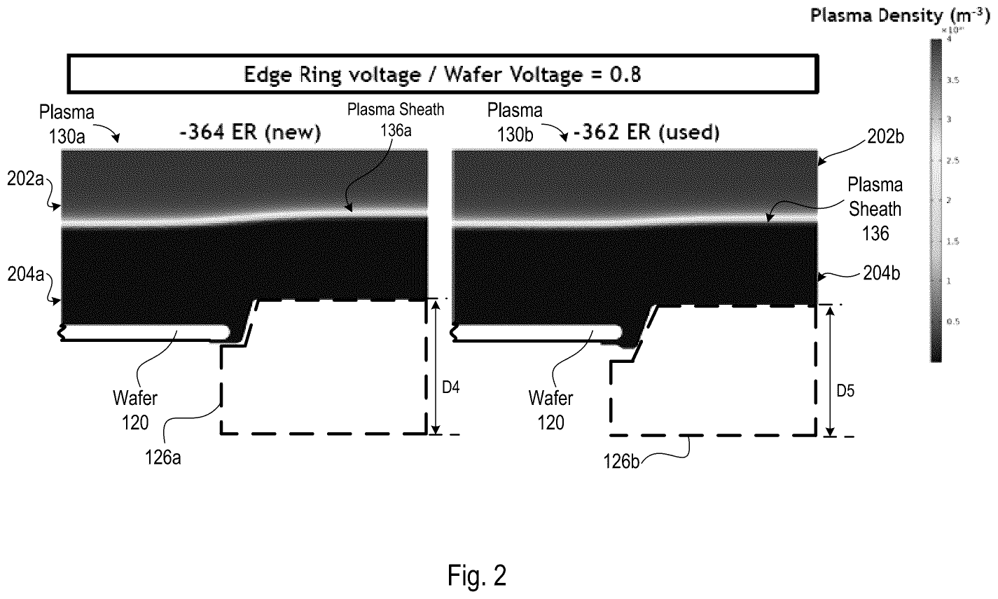

FIG. 2 illustrates plasma 130a, 130b, generated during a plasma etching operation using a new edge ring 126a and a used edge ring 126b. In the example shown in FIG. 2, an experiment was conducted to determine how the different edge ring designs would affect the ion angular spread on a wafer 120 during etching of the wafer. As shown, the new edge ring 126a surrounds the wafer 120 and is defined by a height D4. The height D4 of new edge ring 126a extends from a bottom surface of the new edge ring 126a to a top surface of the new edge ring 126a. As further illustrated, the used edge ring 126b is defined by a height D5. The height D5 of the used edge ring 126b extends from a bottom surface of the used edge ring 126b to a top surface of the used edge ring 126b. In one embodiment, the height D5 of the used edge ring 126b is about 11 millimeters less than the height D4 of the new edge ring 126a. In other embodiments, the used edge ring 126b has a different chamfer profile than the new edge ring 126a. In another embodiment, the used edge ring 126b includes a dip at the bottom of the chamfer.

The experiment conducted with respect to the new edge ring 126a and the used edge ring 125b in FIG. 2 assumes a fixed applied edge ring voltage (V_{AER}) to applied wafer voltage (V_{AW}), e.g., V_{AER}/V_{AW}. In the example, a ratio of V_{AER} to V_{AW} (V_{AER}/V_{AW}) of 0.8 is applied. Using a V_{AER}/V_{AW} of about 0.8 results in the formation of plasma 130a-130b having different plasma density profiles forming above the wafer 120 and respective edge rings 126a-126b. For example, referring to the plasma 130a, a profile of the plasma that is formed above the wafer 120 and the new edge ring 126a. The profile of the plasma 130a includes a high-density section 202a and a low-density section 204a that is separated by plasma sheath 136a. As shown, the high-density section 202a has a plasma density of approximately 3.8⁻³ and the low-density section 204a has a plasma density of approximately 0.5⁻³. In another example, referring to the plasma 130b profile that is formed above the wafer 120 and the used edge ring 126b, the profile of plasma 130b includes a high-density section 202b and a low-density section 204b that is separated by plasma sheath 136b. As shown, the high-density section 202b has a plasma density of approximately 3.8 m³ and the low-density section 204b has a plasma density of approximately 0.5 m⁻³.

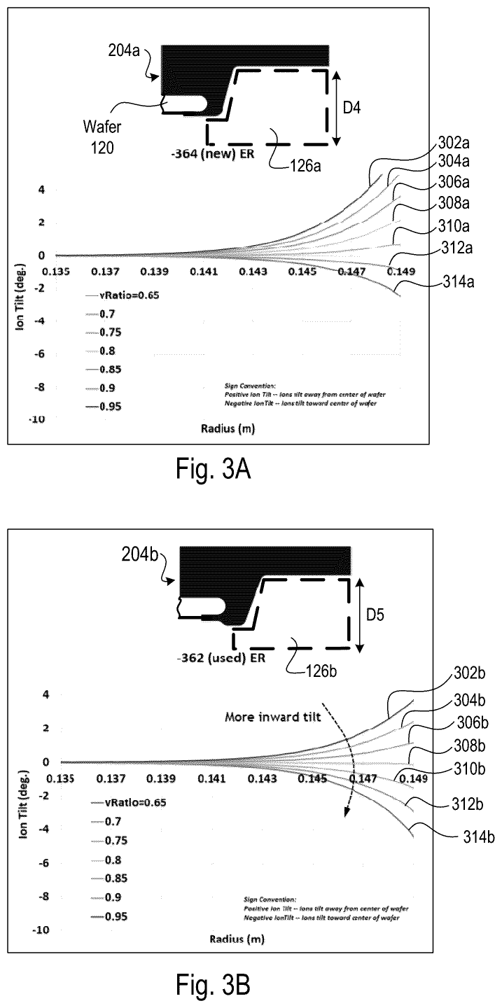

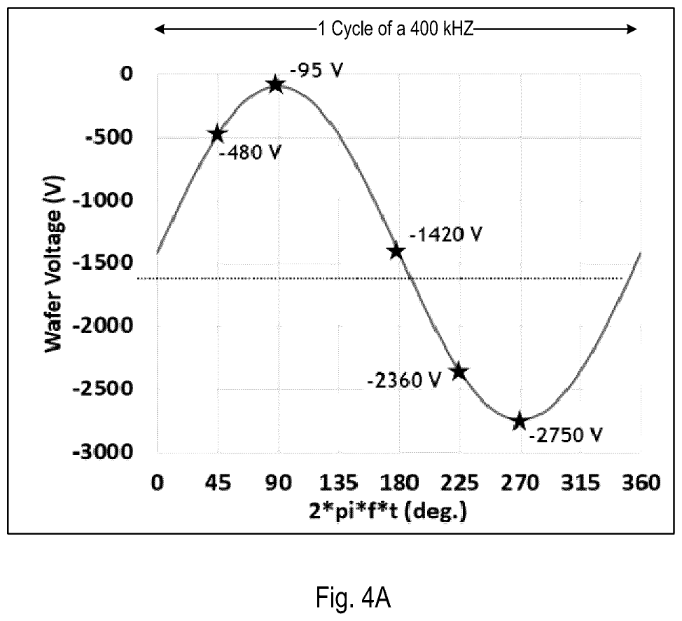

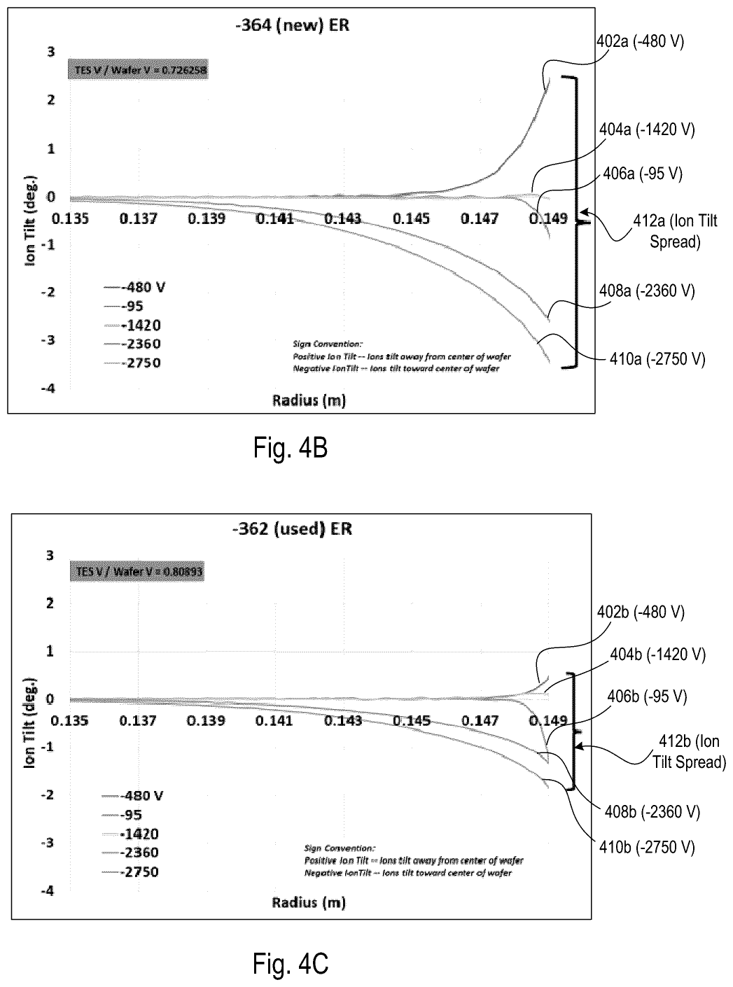

By way of the structure construction of the used edge ring 126b relative to the new edge ring 126a, it was observed that the used edge ring 126b resulted in a lower ion tilt compared to the new edge ring 126a (additional details discussed below with respect to FIGS. 3A-3B and FIGS. 4A-4C).

FIGS. 3A-3B illustrate a plot of ion tilt angle (degrees) versus radial location along the top surface of the wafer 120 for the new edge ring 126a and the used edge ring edge ring 126b, in accordance with the implementations of FIG. 2. Referring to FIG. 3A, the figure illustrates the ion tilt angle versus radial location along the top surface of the wafer 120 for the new edge ring 126a where different V_{AER}/V_{AW} ratios are used to produce the plot. For reference, the low-density section 204a of the plasma 130a is displayed above the plot. As illustrated, the ion tilt angles for radial locations from approximately 0.135 m to 0.149 m (near the edge for a 0.30 m diameter substrate) are shown on the plot when V_{AER}/V_{AW} ratios of 0.65, 0.7, 0.75, 0.8, 0.85, 0.9, and 0.95 are applied. As shown, when V_{AER}/V_{AW} ratios of 0.65 (ref. 314a), 0.7 (ref. 312a), 0.75 (ref. 310a), 0.8 (ref. 308a), 0.85 (ref. 306a), 0.9 (ref. 304a), and 0.95 (ref. 302a) are applied, the ion tilt angle increases as the radial location approaches the extreme edge of the wafer 120 (approaching 0.149 m). For example, at radial location 0.149 m, for a V_{AER}/V_{AW} ratio of 0.8 (ref. 308a), the ion tilt angle is approximately 2.1 degrees. In another example, at radial location 0.149 m, for a V_{AER}/V_{AW} ratios of 0.65 (ref. 314a), the ion tilt angle is approximately-2.5 degrees. As further illustrated in FIG. 3A, a positive ion tilt angle indicates that the ions tilt away from the center of the wafer 120. Further, a negative tilt angle indicates that the ions tilt toward the center of the wafer 120.

FIG. 3B illustrates the ion tilt angle versus radial location along the top surface of the wafer 120 for the used edge ring 126b where different V_{AER}/V_{AW} ratios are used to produce the plot. For reference, the low-density section 204b of the plasma 130b is displayed above the plot. As illustrated, the ion tilt angles for radial locations from approximately 0.135 m to 0.149 m (near the edge for a 0.30 m diameter substrate) are shown on the plot when V_{AER}/V_{AW} ratios of 0.65, 0.7, 0.75, 0.8, 0.85, 0.9, and 0.95 are applied. As shown, when V_{AER}/V_{AW} ratios of 0.65 (ref. 314b), 0.7 (ref. 312b), 0.75 (ref. 310b), 0.8 (ref. 308b), 0.85 (ref. 306b), 0.9 (ref. 304b), and 0.95 (ref. 302b) are applied, the ion tilt angle increases as the radial location approaches the extreme edge of the wafer 120 (approaching 0.149 m). As further illustrated in FIG. 3B, as the ion tilt angle decreases, the ions tilt toward a direction toward the center of the wafer 120. A comparison of the plot for the new edge ring 126a (FIG. 3A) and the used edge ring 126b (FIG. 3B) indicates that the new edge ring 126a has a larger positive ion tilt angle compared to the used edge ring 126b for a given applied V_{AER}/V_{AW} ratio at any point along the radius of the wafer 120. As a result, changes to the ion tilt angle are a result of the elevation differences between the new edge ring 126a and the used edge ring 126b.

FIG. 4A illustrates an embodiment of a graph to illustrate a wafer voltage (Vw) waveform signal generated by a low frequency (LF) radio frequency (RF) pulse generator. As shown, the graph includes a plot of the wafer voltage (Vw) versus the wafer position in degrees for one cycle of a 400 KHz frequency. As shown in the example, the wafer voltage (Vw) waveform signal has a maximum value of −95 V and a minimum value of −2750 for the cycle. To analyze the impact of what various wafer voltages might have on the ion tilt spread, a total of five wafer voltages are selected from the graph to demonstrate the range of the ion tilt spread for a new edge ring 126a and a used edge ring 126b configuration. In particular, wafer voltages of −480 V, −95 V, −1420 V, −2360, and −2750 V are selected for the analysis.

FIGS. 4B-4C illustrate a plot of ion tilt angle (degrees) versus radial location along the top surface of the wafer 120 for a new edge ring and a used edge ring, respectively. Referring to FIG. 4B, the figure illustrates the ion tilt angle versus radial location along the top surface of the wafer 120 for the new edge ring 126a where a fixed ratio of V_{AER}/V_{AW} is chosen and various wafer voltages (see FIG. 4A) are used to produce the plot. In particular, the analysis used a V_{AER}/V_{AW} of 0.726 and wafer voltages of −480 V, −95 V, −1420 V, −2360, and −2750 V for the analysis. The ratio V_{AER}/V_{AW} of 0.726 was chosen for the analysis since the ratio resulted in an ion tilt that had the lowest ion tilt angle (See FIG. 3A). In some embodiments, the V_{AER}/V_{AW} ratio can be 0 to any positive number.

As further illustrated in FIG. 4A, the ion tilt angle for radial locations from approximately 0.135 m to 0.149 m (near the edge for a 0.30 m diameter substrate) are shown on the plot when wafer voltages of −480 V, −95 V, −1420 V, −2360, and −2750 V are applied. As shown, when wafer voltages-480 V (ref. 402a), −95 V (ref. 406a), −1420 V (ref. 404a), −2360 (ref.408a), and −2750 V (ref.410a) are applied, the ion tilt angle increases as radial location approaches the extreme edge of the wafer 120 (approaching 0.149 m). For example, at radial location 0.149 m, the ion tilt angle ranges between approximately positive 2.5 degrees and negative 3.5 degrees which is illustrated by ion tilt spread 412a. As further illustrated in FIG. 4A, a positive ion tilt angle indicates that the ions tilt away from the center of the wafer 120. Further, a negative tilt angle indicates that the ions tilt toward the center of the wafer 120.

FIG. 4C illustrates the ion tilt angle versus radial location along the top surface of the wafer 120 for the used edge ring 126b where a fixed ratio of V_{AER}/V_{AW} is chosen and various wafer voltages (see FIG. 4A) are used to produce the plot. In particular, the analysis used a ratio V_{AER}/V_{AW} ratio 0.808 and wafer voltages of −480 V, −95 V, −1420 V, −2360, and −2750 V for the analysis. The ratio V_{AER}/V_{AW} of 0.808 was chosen for the analysis since the ratio resulted in an ion tilt that had the lowest ion tilt angle (See FIG. 3B). As further illustrated in FIG. 4C, the ion tilt angle for radial locations from approximately 0.135 m to 0.149 m (near the edge for a 0.30 m diameter substrate) are shown on the plot when the wafer voltages are applied. As shown, when wafer voltages-480 V (ref. 402b), −95 V (ref. 406b), −1420 V (ref. 404b), −2360 (ref. 408b), and −2750 V (ref. 410b) are applied, the ion tilt angle increases as radial location approaches the extreme edge of the wafer 120 (approaching 0.149 m). For example, at radial location 0.149 m, the ion tilt angle ranges between approximately positive 0.5 degrees and negative 2.0 degrees which is illustrated by ion tilt spread 412b. Accordingly, a comparison of the plot for the new edge ring 126a (FIG. 4B) and the used edge ring 126b (FIG. 4C) indicates that the used edge ring 126b has a smaller ion tilt spread 412b than the ion tilt spread 412a of the new edge ring 126a.

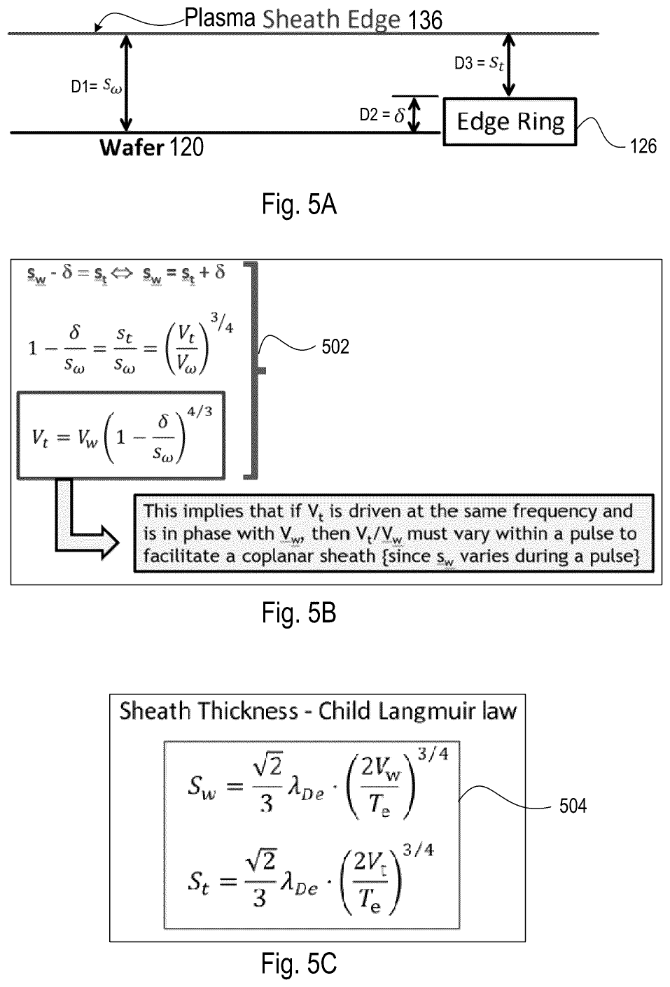

FIGS. 5A-5C illustrate the plasma sheath dynamics where the Child-Langmuir Law theorem is applied to demonstrate the required edge ring voltage and the wafer voltage that would cause the plasma sheath at the edge ring to be coplanar with the plasma sheath along the wafer. Referring to FIG. 5A, the figure illustrates a conceptual illustration of the position of the edge of plasma sheath 136 relative to the wafer 120 and the edge ring 126. As shown, distance Sω (e.g., D1) extends from the top surface of the wafer 120 to the edge of the plasma sheath 136. As further illustrated, distance 8 (e.g., D2) extends from the top surface of the wafer 120 to the top surface of the edge ring 126. As further illustrated, distance St (e.g., D3) extends from the top surface of the edge ring 126 to the edge of the plasma sheath 136.

Referring to FIG. 5B, the analysis 502 implies that if Vt (e.g., edge ring voltage) is driven at the same frequency and is in phase with Vw (e.g., wafer voltage), then the ratio of Vt/Vw (e.g., edge ring voltage to wafer voltage) must vary within a pulse to facilitate a coplanar plasma sheath along the edge ring and the wafer since distance Sω varies during a pulse. Referring to FIG. 5C, under the Child-Langmuir Law theorem, equations 504 provide respective equations for distance Sω and distance St where ADE is defined as the Debye length and Tₑ is defined as the temperature of electrons.

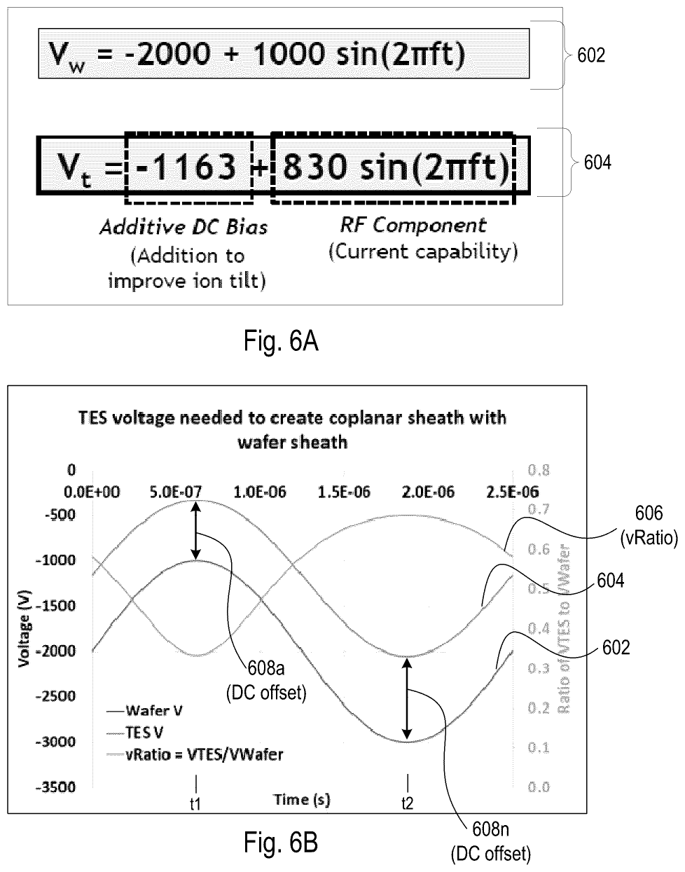

FIGS. 6A-6B illustrate an example an edge ring voltage (V_{ER}) waveform 604 and a wafer voltage (Vw) waveform 602 that can provide a coplanar plasma sheath edge along the edge ring and the wafer. For exemplary purposes, it is assumed that the plasma density (ne) is Se 10 cm⁻³, the distance 8 (e.g., D2) from the top surface of the wafer 120 to the top surface of the edge ring 126 is 2 mm, and the temperature of electrons (Te) is 3 eV. As shown in FIG. 6A, the Vw waveform 602 is defined by the equation, Vw=−2000+1000 sin (2πft) where the frequency is 400 kHz. In the example, the Vw waveform 602 includes an induced DC bias component of −2000 V and an RF component (e.g., 1000 sin (2πft)). As further illustrated, the V_{ER} waveform 604 is defined by the equation, Vt=−1163+830 sin (2πft) where the frequency is 400 KHz. In the example, the V_{ER} waveform 604 includes an additive DC bias component of −1163 V and an RF component (e.g., 1000 sin (830 sin (2πft)).

FIG. 6B illustrates the plot of the V_{ER} waveform 604, the Vw waveform 602, and the ratio of the edge ring voltage to wafer voltage (e.g., vRatio 606). In particular, FIG. 6B illustrates a plot of voltage versus time. The plot shows the edge ring voltage (e.g., TES voltage) that is needed to cause the plasma sheath edge along the edge ring to be coplanar with the plasma sheath edge along the wafer which can in turn cause the reduction (or elimination) in the ion angular spread. As shown, the V_{ER} waveform 604 has the same frequency as the Vw waveform 602. Further, the V_{ER} waveform 604 and the Vw waveform 602 is in phase and has a different DC offset 608 and a different amplitude. For example, as illustrated in FIG. 6B, at time tl, the V_{ER} waveform 604 has a DC offset 608a from the Vw waveform 602 by a magnitude that is approximately 525 V. In some embodiments, the DC offset can be any value, 0, positive or negative.

The plot shown in FIG. 6B further illustrates the ratio of the edge ring voltage to wafer voltage (e.g., vRatio 606) versus time. As shown, the ratio of the edge ring voltage to wafer voltage changes during application of the V_{ER} waveform 604 and the Vw waveform 602. In one embodiment, the changes in the vRatio 606 can cause a reduction in ion tilt angles near an edge of the wafer 120 and proximate to the edge ring 126 during the etching process.

Accordingly, the application of the V_{ER} waveform 604 that includes the additive DC bias component can cause the plasma sheath along the edge ring 126 to becomes coplanar with the plasma sheath along the wafer sheath during a given pulse. As noted above, the additive DC bias component can cause a reduction (or elimination) in the ion angular spread if distance D1 is greater than D2. As described above, distance D1 extends from the top surface of the wafer 120 to the edge of the plasma sheath 136 and D2 extends from the top surface of the wafer 120 to the top surface of the edge ring 126. Further, if distance D1 is approximately the same as distance D2, or if D1 is less than D2, the ion energies would be so small causing the ion angular spread to be negligible.

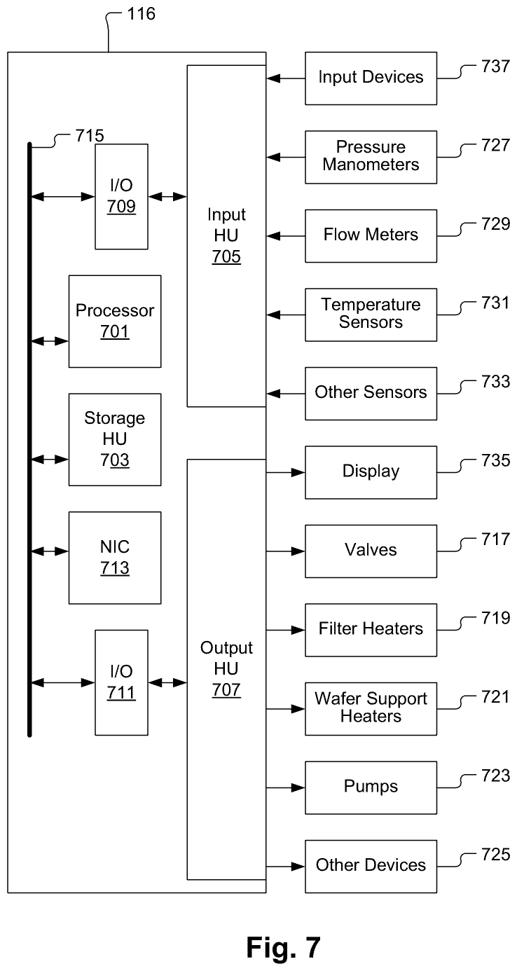

FIG. 7 shows an example schematic of the control system 116 of FIG. 1A, in accordance with some embodiments. In some embodiments, the control system 116 is configured as a process controller for controlling the semiconductor fabrication process performed in a plasma processing system. In various embodiments, the control system 116 includes a processor 701, a storage hardware unit (HU) 703 (e.g., memory), an input HU 705, an output HU 707, an input/output (I/O) interface 709, an I/O interface 711, a network interface controller (NIC) 713, and a data communication bus 715. The processor 701, the storage HU 703, the input HU 705, the output HU 707, the I/O interface 709, the I/O interface 711, and the NIC 713 are in data communication with each other by way of the data communication bus 715. The input HU 705 is configured to receive data communication from a number of external devices. Examples of the input HU 705 include a data acquisition system, a data acquisition card, etc. The output HU 707 is configured to transmit data to a number of external devices.

An example of the output HU 707 is a device controller. Examples of the NIC 713 include a network interface card, a network adapter, etc. Each of the I/O interfaces 709 and 711 is defined to provide compatibility between different hardware units coupled to the I/O interface. For example, the I/O interface 709 can be defined to convert a signal received from the input HU 705 into a form, amplitude, and/or speed compatible with the data communication bus 715. Also, the I/O interface 707 can be defined to convert a signal received from the data communication bus 715 into a form, amplitude, and/or speed compatible with the output HU 707. Although various operations are described herein as being performed by the processor 701 of the control system 116, it should be understood that in some embodiments various operations can be performed by multiple processors of the control system 116 and/or by multiple processors of multiple computing systems in data communication with the control system 116.

In some embodiments, the control system 116 is employed to control devices in various wafer fabrication systems based in-part on sensed values. For example, the control system 116 may control one or more of valves 717, filter heaters 719, wafer support structure heaters 721, pumps 723, and other devices 725 based on the sensed values and other control parameters. The valves 717 can include valves associated with control of a backside gas supply system, a process gas supply system, and a temperature control fluid circulation system. The control system 116 receives the sensed values from, for example, pressure manometers 727, flow meters 729, temperature sensors 731, and/or other sensors 733, e.g., voltage sensors, current sensors, etc. The control system 116 may also be employed to control process conditions within the plasma processing system during performance of plasma processing operations on the wafer 104. For example, the control system 116 can control the type and amounts of process gas(es) supplied from the process gas supply system to the plasma process chamber. Also, the control system 116 can control operation of a DC supply for the clamp electrode(s) 202. The control system 116 can also control operation of a lifting device for the lift pins. The control system 116 also controls operation of the backside gas supply system and the temperature control fluid circulation system. The control system 116 also controls operation of pump that controls removal of gaseous byproducts from the chamber 102. It should be understood that the control system 116 is equipped to provide for programmed and/or manual control any function within the plasma processing system.

In some embodiments, the control system 116 is configured to execute computer programs including sets of instructions for controlling process timing, process gas delivery system temperature, and pressure differentials, valve positions, mixture of process gases, process gas flow rate, backside cooling gas flow rate, chamber pressure, chamber temperature, wafer support structure temperature (wafer temperature), RF power levels, RF frequencies, RF pulsing, impedance matching system settings, cantilever arm assembly position, bias power, and other parameters of a particular process. Other computer programs stored on memory devices associated with the control system 116 may be employed in some embodiments. In some embodiments, there is a user interface associated with the control system 116. The user interface includes a display 735 (e.g., a display screen and/or graphical software displays of the apparatus and/or process conditions), and user input devices 737 such as pointing devices, keyboards, touch screens, microphones, etc.

Software for directing operation of the control system 116 may be designed or configured in many different ways. Computer programs for directing operation of the control system 116 to execute various wafer fabrication processes in a process sequence can be written in any conventional computer readable programming language, for example: assembly language, C, C++, Pascal, Fortran or others. Compiled object code or script is executed by the processor 701 to perform the tasks identified in the program. The control system 116 can be programmed to control various process control parameters related to process conditions such as, for example, filter pressure differentials, process gas composition and flow rates, backside cooling gas composition and flow rates, temperature, pressure, plasma conditions, such as RF power levels and RF frequencies, bias voltage, cooling gas/fluid pressure, and chamber wall temperature, among others. Examples of sensors that may be monitored during the wafer fabrication process include, but are not limited to, mass flow control modules, pressure sensors, such as the pressure manometers 727 and the temperature sensors 731. Appropriately programmed feedback and control algorithms may be used with data from these sensors to control/adjust one or more process control parameters to maintain desired process conditions.

In some implementations, the control system 116 is part of a broader fabrication control system. Such fabrication control systems can include semiconductor processing equipment, including a processing tools, chambers, and/or platforms for wafer processing, and/or specific processing components, such as a wafer pedestal, a gas flow system, etc. These fabrication control systems may be integrated with electronics for controlling their operation before, during, and after processing of the wafer. The control system 116 may control various components or subparts of the fabrication control system. The control system 116, depending on the wafer processing requirements, may be programmed to control any of the processes disclosed herein, including the delivery of processing gases, the delivery of backside cooling gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the control system 116 may be defined as electronics having various integrated circuits, logic, memory, and/or software that receive instructions, issue instructions, control operation, enable wafer processing operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the control system 116 in the form of various individual settings (or program files), defining operational parameters for carrying out a particular process on the wafer within the system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The control system 116, in some implementations, may be a part of or coupled to a computer that is integrated with, coupled to the plasma processing system, or otherwise networked to the system, or a combination thereof. For example, the control system 116 may be in the “cloud” of all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to the system over a network, which may include a local network or the Internet.

The remote computer may include a user interface that enables entry or programming of parameters and/or settings, which are then communicated to the system from the remote computer. In some examples, the control system 116 receives instructions in the form of data, which specify parameters for each of the processing steps to be performed during one or more operations. It should be understood that the parameters may be specific to the type of process to be performed within the plasma processing system. Thus, as described above, the control system 116 may be distributed, such as by comprising one or more discrete controllers that are networked together and working towards a common purpose, such as the processes and controls described herein. An example of a distributed controller for such purposes would be one or more integrated circuits on the plasma processing system in communication with one or more integrated circuits located remotely (such as at the platform level or as part of a remote computer) that combine to control a process performed on the plasma processing system.

Without limitation, example systems that the control system 116 can interface with may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers. As noted above, depending on the process step or steps to be performed by the tool, the control system 116 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory. Embodiments described herein may also be implemented in conjunction with various computer system configurations including hand-held hardware units, microprocessor systems, microprocessor-based or programmable consumer electronics, minicomputers, mainframe computers and the like. Embodiments described herein can also be implemented in conjunction with distributed computing environments where tasks are performed by remote processing hardware units that are linked through a network. It should be understood that the embodiments described herein, particularly those associated with the control system 116, can employ various computer-implemented operations involving data stored in computer systems. These operations are those requiring physical manipulation of physical quantities. Any of the operations described herein that form part of the embodiments are useful machine operations. The embodiments also relate to a hardware unit or an apparatus for performing these operations. The apparatus may be specially constructed for a special purpose computer. When defined as a special purpose computer, the computer can also perform other processing, program execution or routines that are not part of the special purpose, while still being capable of operating for the special purpose. In some embodiments, the operations may be processed by a general purpose computer selectively activated or configured by one or more computer programs stored in the computer memory, cache, or obtained over a network. When data is obtained over a network, the data may be processed by other computers on the network, e.g., a cloud of computing resources.

Various embodiments described herein can be implemented through process control instructions instantiated as computer-readable code on a non-transitory computer-readable medium. The non-transitory computer-readable medium is any data storage hardware unit that can store data, which can be thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes, and other optical and non-optical data storage hardware units. The non-transitory computer-readable medium can include computer-readable tangible medium distributed over a network-coupled computer system so that the computer-readable code is stored and executed in a distributed fashion.

Although the foregoing disclosure includes some detail for purposes of clarity of understanding, it will be apparent that certain changes and modifications can be practiced within the scope of the appended claims. For example, it should be understood that one or more features from any embodiment disclosed herein may be combined with one or more features of any other embodiment disclosed herein. Accordingly, the present embodiments are to be considered as illustrative and not restrictive, and what is claimed is not to be limited to the details given herein, but may be modified within the scope and equivalents of the described embodiments.

What is claimed is:

1. A system for etching a wafer, the system comprising:
a lower electrode and an upper electrode disposed above the lower electrode;
an edge ring surrounding the lower electrode;
a first radio frequency (RF) generator electrically coupled to the lower electrode and a second radio frequency (RF) generator electrically coupled to the edge ring;
a direct current (DC) bias generator for electrically supplying an additive DC bias to the edge ring; and
a controller interfaced with the first and second RF generators and the DC bias generator, the first RF generator is configured to produce a wafer voltage (Vw) waveform at the lower electrode, the produced Vw waveform includes an induced direct current (DC) component and a first RF component produced by the first RF generator, wherein the controller is configured to produce an edge ring voltage (V_{ER}) waveform for application to the edge ring, the V_{ER} waveform includes the additive DC bias and a second RF component produced by the second RF generator,
wherein the V_{ER} waveform is programmed by the controller to have a substantially same frequency and phase as the Vw waveform, a DC offset from the Vw waveform, and an amplitude variation relative to an amplitude of the Vw waveform.

2. The system of claim 1, wherein a ratio of applied edge ring voltage to applied wafer voltage (V_{AER}/V_{AW}) changes during application of the V_{ER} waveform.

3. The system of claim 2, wherein said changes in the V_{AER}/V_{AW} ratio causes a change in ion tilt and ion tilt spread near an edge of the wafer and proximate to said edge ring during said etching.

4. The system of claim 3, wherein said ion tilt is an incidence angle that is other than normal to a surface of the wafer, or normal to the surface of the wafer.

5. The system of claim 4, wherein said incidence angle includes a negative angle or a positive angle, or a combination thereof, said ion tilt having the positive angle tilts in a direction away from a center point of the wafer, said ion tilt having the negative angle tilts in a direction toward the center of the wafer.

6. The system of claim 3, wherein said V_{AER}/V_{AW} ratio has a value ranging from about 0.3 to 0.7.

7. The system of claim 3, wherein the additive DC bias causes the change in the ion tilt near the edge of the wafer and proximate to said edge ring during said etching.

8. The system of claim 1, wherein application of the Vw waveform and the V_{ER} waveform during said etching causes a plasma sheath that is defined over the wafer and the edge ring, a portion of the plasma sheath that is defined over the wafer is substantially coplanar with a portion of the plasma sheath defined over the edge ring.

9. The system of claim 8, wherein the application of the Vw waveform and the V_{ER} waveform during said etching reduces ion tilt near an edge of the wafer, said reduction in the ion tilt causes one or more ions to be substantially normal to a top surface of the wafer.

10. The system of claim 8, wherein a first distance extending from a top surface of the wafer to a lower edge of the plasma sheath is greater than a second distance extending from the top surface of the wafer to a top surface of the edge ring.

11. The system of claim 1, wherein a top surface of the wafer is disposed below a top surface of the edge ring, or at a substantially same elevation to the top surface of the edge ring, or below the top surface of the edge ring.

12. The system of claim 1, wherein the DC offset from the Vw waveform has a magnitude value ranging about 500 V to 1,000 V.

13. The system of claim 1, wherein a frequency operation of the first RF generator and the second RF generator is about 400 KHz.

14. The system of claim 1, further comprising a third radio frequency (RF) generator electrically coupled to the upper electrode, wherein a frequency operation of the third RF generator is greater than the frequency operation of the first generator and the second generator.

15. A method for etching a wafer in a plasma system, comprising:
the plasma system includes a lower electrode and an upper electrode disposed above the lower electrode, and an edge ring that surrounds the lower electrode;
connecting a first radio frequency (RF) generator to the lower electrode and a second radio frequency (RF) generator to the edge ring;
connecting a direct current (DC) bias generator to the edge ring for supplying an additive DC bias to the edge ring, wherein the first RF generator is configured to produce a wafer voltage (Vw) waveform at the lower electrode, the produced Vw waveform includes an induced direct current (DC) component and a first RF component produced by the first RF generator; and
generating an edge ring voltage (V_{ER}) waveform for application to the edge ring, the V_{ER} waveform includes the additive DC bias and a second RF component produced by the second RF generator, the V_{ER} waveform is set to have a substantially same frequency and phase as the Vw waveform, a DC offset from the Vw waveform, and an amplitude variation relative to an amplitude of the Vw waveform.

16. The method as recited in claim 15, wherein a ratio of applied edge ring voltage to applied wafer voltage (V_{AER}/V_{AW}) changes during application of the V_{ER} waveform, and said changes in the V_{AER}/V_{AW} ratio act cause changes in ion tilt near an edge of the wafer and proximate to said edge ring during said etching.

17. The method as recited in claim 16, wherein said ion tilt is an incidence angle that is other than normal to a surface of the wafer or normal to the surface of the wafer.

18. The method as recited in claim 17, wherein said incidence angle includes a negative angle or a positive angle, or a combination thereof, said ion tilt having the positive angle tilts in a direction away from a center point of the wafer, said ion tilt having the negative angle tilts in a direction toward the center of the wafer.

19. The method as recited in claim 15, wherein application of the Vw waveform and the V_{ER} waveform during said etching causes a plasma sheath that is defined over the wafer and the edge ring, a portion of the plasma sheath that is defined over the wafer is substantially coplanar with a portion of the plasma sheath defined over the edge ring.

20. The method as recited in claim 15, wherein a top surface of the wafer is disposed below a top surface of the edge ring, or at a substantially same elevation to the top surface of the edge ring, or below the top surface of the edge ring.
